(19) United States
(12) Patent Application Publication
(10) Pub. No.: US 2008/0121985 A1
(43) Pub. Date: May 29, 2008

(54) STRUCTURE AND METHOD TO IMPROVE SHORT CHANNEL EFFECTS IN METAL OXIDE SEMICONDUCTOR FIELD EFFECT TRANSISTORS

(75) Inventors: Xiangdong Chen, Poughquag, NY (US); Dae-Gyu Park, Poughquag, NY (US); Jae-Yoon Yoo, Fishkill, NY (US)

Correspondence Address: FREDERICK W. GIBB, III;Gibb & Rahman, LLC, 2568-A RIVA ROAD, SUITE 304, ANNAPOLIS, MD, 21401, US

(73) Assignees: INTERNATIONAL BUSINESS MACHINES CORPORATION, Armonk, NY (US); SAMSUNG ELECTRONICS CO., LTD., Suwon-si (KR)

(21) Appl. No.: 11/557,145

(22) Filed: Nov. 7, 2006

(51) Int. Cl. H01L 27/088; H01L 21/04; H01L 29/78; H01L 21/77

(52) U.S. Cl. 257/327; 438/303; 438/294; 438/218; 438/231; 257/369; 257/E21.066; 257/E21.598; 257/E27.06; 257/E29.255

(57) ABSTRACT

Disclosed are embodiments of improved MOSFET and CMOS structures that provides for increased control over short channel effects. Also disclosed are embodiments of associated methods of forming these structures. The embodiments suppress short channel effects by incorporating buried isolation regions into a transistor below source/drain extension regions and between deep source/drain regions and the channel region and, particularly, between deep source/drain regions and the halo regions. Buried isolation regions between the deep source/drain regions and the channel region minimize drain induced barrier lowering (DIBL) as well as punch through. Additionally, because the deep source/drain regions and halo regions are separated by the buried isolation regions, side-wall junction capacitance and junction leakage are also minimized.

### BACKGROUND

1. Field of the Invention

The embodiments of the invention generally relate to semiconductor devices and, more particularly, to metal oxide semiconductor device structures with improved control over short channel effects.

2. Description of the Related Art

Over the past few decades numerous performance and economic advantages have been seen with semiconductor technology scaling. For example, size scaling of metal oxide semiconductor field effect transistor (MOSFET) has lead to decreased channel lengths and a corresponding increase in switching speeds (i.e., shorter channel lengths correspond to faster switching speeds). However, it has been determined that such scaling has its limits because short channel lengths can lead to undesirable “short-channel effects” particularly in p-type field effect transistors. These short channel effects include, but are not limited, variability in threshold voltage (Vt), excessive drain leakage currents, punch through, and drain induced barrier lowering (DIBL). For example, severe DIBL (e.g., greater than 150 mV) and Vt roll-off has been observed for in 65 nm technology and is even worse for 45 nm technology and beyond.

Various techniques have been used in an attempt to control such short channel effects. For example, halos can be incorporated into MOSFETs to reduce the short channel effects. Specifically, these halos are highly doped regions having the same conductivity type as the transistor body and are positioned around the edges of the source/drain extensions below the gate. Such halos reduce the depletion region between the source/drain regions and the channel region and, thereby, reduce punch through (i.e., reduce lateral diffusion of dopants from the source/drain regions into the channel region). The strength of the halo effect depends on both the doping concentration of the halo and on confinement of the halo dopants. However, the high halo dose that is used to control the short channel effects can also cause large junction leakage, large side-wall junction capacitance and large Vt roll-up. Consequently, controlling these short channel effects has proven difficult to the point of limiting scaling of conventional MOSFETs.

Therefore, there is a need in the art for metal oxide semiconductor devices that have improved control over short channel effects, thereby allowing for continued size scaling.

### SUMMARY OF THE INVENTION

In view of the foregoing, disclosed herein are embodiments of both an improved metal oxide semiconductor field effect transistor (MOSFET) structure and an improved complementary metal oxide semiconductor (CMOS) device structure. These MOSFET and CMOS structures provide for increased control over short channel effects. Also disclosed are embodiments of associated methods of forming these structures. The embodiments suppress short channel effects by incorporating buried isolation regions into a transistor below source/drain extension regions and between deep source/drain regions and the channel region and, particularly, between deep source/drain regions and halo regions.

More particularly, embodiments of the MOSFET structure comprise a semiconductor layer with source/drain extension regions, halo regions, deep source/drain regions, and a channel region. A gate is positioned the top surface of a semiconductor layer above the channel region. Sidewall spacers are located adjacent to the opposing sidewalls of the gate.

The source/drain extension regions are at the top surface of the semiconductor layer immediately below the sidewall spacers. The halo regions are below the source/drain extension regions. The deep source/drain regions extend into the semiconductor layer a predetermined depth from the top surface and are positioned laterally adjacent to the source/drain extension regions and the halo regions. The deep source/drain regions can comprise an epitaxial silicon, an epitaxial silicon germanium, an epitaxial silicon carbide, an epitaxial silicon germanium carbide, or any other suitable semiconductor material. The channel region is positioned below the gate between the source/drain extension regions and halo regions.

The transistor structure further comprises buried isolation regions (e.g., buried nitride or oxide regions) within the semiconductor layer. These buried isolation regions can be below the level of the source/drain extension regions and can be between the deep source/drain regions and the channel region and, particularly, between the deep source/drain regions and the halo regions in order to suppress short channel effects. Buried isolation regions between the deep source/drain regions and channel region minimize drain induced barrier lowering (DIBL) as well as punch through. Additionally, because the deep source/drain regions and halo regions are separated by the buried isolation regions, side-wall junction capacitance and junction leakage are also minimized.

Also disclosed are embodiments of complementary metal oxide semiconductor device (CMOS) structure that comprises a p-type field effect transistor (pFET) coupled to an n-type field effect transistor (nFET). The pFET can comprise deep source/drain regions and source/drain extension regions that are doped with a p-type dopant and halo regions that are highly doped with an n-type dopant. The pFET can further comprise buried isolation regions between the deep source/drain regions and the halo regions to suppress short channel effects. The nFET can comprise deep source/drain regions and source/drain extensions regions that are doped with an n-type dopant. Because nFETs are not as susceptible to such short channel effects as pFETs, the nFETcan optionally be formed without the halo regions and/or the buried isolation regions.

Also, disclosed are embodiments of a method of forming a MOSFET structure, as described above, as well as a method of forming a CMOS device structure that incorporates such a MOSFET structure.

More particularly, an embodiment of a method of forming a MOSFET structure comprises forming shallow trench isolation structures (STIs) within a semiconductor layer to define the active semiconductor region of the transistor. Then, a gate is formed on a top surface of the semiconductor layer and, particularly, on the top surface of the region defined by the STIs.

A first layer of sidewall spacers is formed on the opposing sidewalls of the gate. Then, a second type dopant can be implanted a predetermined depth into the semiconductor layer on both sides of the gate in order to form halo regions. Additionally, a first type dopant can be implanted into the top surface of the semiconductor layer on both sides of the gate above the second type dopant (i.e., above the halo regions) in order to form source/drain extension regions.

Once the source/drain extension regions and the halo regions are implanted, a second layer of sidewall spacers is formed on the first layer. Thus, multi-layered sidewall spacers are formed adjacent to the opposing sidewalls of the gate.

Trenches are then etched into the semiconductor layer on both sides of the gate. The trenches are etched such that they extend between the sidewall spacers and the shallow trench isolation structures that define the active silicon region. Thus, the trench walls closest to the gate are aligned below the sidewall spacers. The depth of the trenches can be approximately equal to the predetermined depth at which the second type dopant is implanted to form the halo regions.

An insulator layer is then formed on the trench walls closest to the gate and the trenches are partially filled with a selected semiconductor material. This can be accomplished, for example, by performing an epitaxial deposition process such that the selected semiconductor material (e.g., silicon, silicon germanium, silicon carbide, silicon germanium carbide, etc.) is grown from the semiconductor layer that is exposed at the bottom of the trenches. The selected semiconductor material is only grown vertically because the sides of the trenches are formed of insulating material from the STIs or insulator layer.

Once the trenches are partially filled with the selected semiconductor material, the exposed portions of the insulator layer are removed and the remaining portions of the trenches are filled with the selected semiconductor material. This can be accomplished, for example, by performing a second epitaxial deposition process. During this second epitaxial deposition process, the selected semiconductor material is grown both vertically from the semiconductor material that is already partially filling the trenches and horizontally from the trench walls exposed below the sidewall spacers and above the remaining insulator layer.

Once the trenches are completely filled and the buried isolation regions are formed, the selected semiconductor material within the trenches can be implanted with a first type dopant in order to form the deep source/drain regions. These deep source/drain regions are, thus, separated from the halo regions as well as the channel region by the buried isolation regions.

An embodiment of a method of forming a CMOS device structure that incorporates such a MOSFET structure comprises forming shallow trench isolation structures (STIs) within a semiconductor layer to define the active semiconductor regions for multiple transistors. That is, a first section of the semiconductor layer can be delineated for a p-type field effect transistor (pFET) and a second section of the semiconductor layer can be delineated for an n-type field effect transistor (nFET)).

Then, first and second gates are formed on the first and second sections, respectively of the semiconductor layer and a first layer of sidewall spacers is formed on the opposing sidewalls of the first and second gates.

Then, masked implantation processes can be used to form halo regions for the pFET and, optionally, for the nFET as well as source/drain extension regions for both FETs. Specifically, an n-type dopant can be implanted a predetermined depth into the semiconductor layer on both sides of the first gate in order to form halo regions for the pFET. A p-type dopant can similarly be implanted a predetermined depth into the semiconductor layer on both sides of the second gate in order to form halo regions for the nFET. Additionally, a p-type dopant can be implanted into the top surface of the semiconductor layer on both sides of the first gate above the n-type dopant (i.e., above the halo regions for the pFET) in order to form source/drain extension regions for the pFET and an n-type dopant can be implanted into the top surface of the semiconductor layer on both sides of the second gate in order to form source/drain extension regions for the nFET.

Once the source/drain extension regions and the halo regions are implanted, a second layer of sidewall spacers is formed on each gate. Thus, multi-layered sidewall spacers are formed.

Trenches are then etched into the semiconductor layer in the first section on both sides of the first gate. The trenches are etched such that they extend between the sidewall spacers on the first gate and the shallow trench isolation structures that define the first section. Thus, the trench walls closest to the first gate are aligned below the sidewall spacers that are on the first gate. The depth of the trenches can be approximately equal to the predetermined depth at which the n-type dopant is implanted in the first section to form the halo regions.

An insulator layer is then formed on the trench walls closest to the first gate and the trenches are partially filled with a selected semiconductor material (e.g., silicon, silicon germanium, silicon carbide, silicon germanium carbide, etc.). This can be accomplished, for example, by performing an epitaxial deposition process such that the selected semiconductor material is grown from the semiconductor layer that is exposed at the bottom of the trenches. The selected semiconductor material is only grown vertically because the sides of the trenches are formed of insulating material from the STIs or insulator layer.

Once the trenches are partially filled with the selected semiconductor material, the exposed portions of the insulator layer are removed and the remaining portions of the trenches are filled with the selected semiconductor material. This can be accomplished, for example, by performing a second epitaxial deposition process. During this second epitaxial deposition process, the selected semiconductor material is grown both vertically from the selected semiconductor material that is already partially filling the trenches and horizontally from the trench walls exposed below the sidewall spacers and above the remaining insulator layer.

Once the trenches are completely filled and the buried isolation regions are formed, masked implantation processes can be used to form the deep source/drain regions in both the first and second sections. That is, the selected semiconductor material within the trenches can be implanted with a p-type dopant in order to form the deep source/drain regions of the pFET. These deep source/drain regions are, thus, separated from the halo regions as well as the channel region of the pFET by the buried isolation regions. Additionally, the semiconductor layer in the second section on both sides of the sidewall spacers can be implanted with an n-type dopant to form the deep source/drain regions of nFET.

These and other aspects of the embodiments of the invention will be better appreciated and understood when considered in conjunction with the following description and the accompanying drawings. It should be understood, however, that the following descriptions, while indicating preferred embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic diagram illustrating structural embodiments of a transistor and of a complementary metal oxide semiconductor (CMOS) device incorporating the transistor;

FIG. 2 is a flow diagram illustrating an embodiment of a method of forming a transistor;

FIG. 3 is a flow diagram illustrating an embodiment of a method of forming a CMOS device;

FIG. 4 is a schematic diagram illustrating a partially completed transistor and a partially completed CMOS device incorporating the transistor;

FIG. 5 is a schematic diagram illustrating a partially completed transistor and a partially completed CMOS device incorporating the transistor;

FIG. 6 is a schematic diagram illustrating a partially completed transistor and a partially completed CMOS device incorporating the transistor;

FIG. 7 is a schematic diagram illustrating a partially completed transistor and a partially completed CMOS device incorporating the transistor;

FIG. 8 is a schematic diagram illustrating a partially completed transistor and a partially completed CMOS device incorporating the transistor;

FIG. 9 is a schematic diagram illustrating a partially completed transistor and a partially completed CMOS device incorporating the transistor;

FIG. 10 is a schematic diagram illustrating a partially completed transistor and a partially completed CMOS device incorporating the transistor;

FIG. 11 is a schematic diagram illustrating a partially completed transistor and a partially completed CMOS device incorporating the transistor;

FIG. 12 is a schematic diagram illustrating a partially completed transistor and a partially completed CMOS device incorporating the transistor; and

FIG. 13 is a schematic diagram illustrating a partially completed transistor and a partially completed CMOS device incorporating the transistor.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

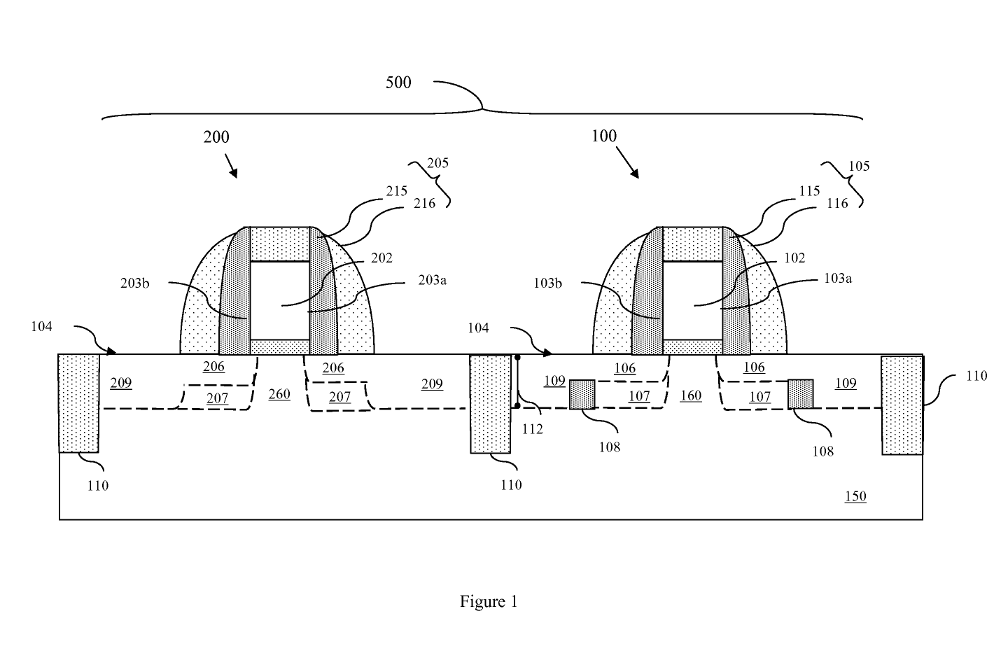

In view of the foregoing, referring to FIG. 1, disclosed herein are embodiments of both an improved metal oxide semiconductor field effect transistor (MOSFET) structure 100 that provides for increased control over short channel effects and an improved complementary metal oxide semiconductor (CMOS) device structure 500 that incorporates the structure 100. Also disclosed are embodiments of associated methods of forming the structures 100 and 500. The embodiments suppress short channel effects by incorporating buried isolation regions 108 into a transistor 100 below the level of source/drain extension regions 106 and between deep source/drain regions 109 and the channel region 160 and, particularly, between deep source/drain regions 109 and halo regions 107. Buried isolation regions 108 between deep source/drain regions 109 and the channel region 160 minimize drain induced barrier lowering (DIBL) as well as punch through. Additionally, because deep source/drain regions 109 and halo regions 107 are separated by buried isolation regions 108, side-wall junction capacitance and junction leakage are also minimized.

More particularly, embodiments of the MOSFET structure 100 comprise a semiconductor layer 150 with source/drain extension regions 106, halo regions 107, deep source/drain regions 109, and a channel region 160. For the purpose of illustration and because p-type field effect transistors (pFETs) are known to be more susceptible to short channel effects, the MOSFET structure 100 will be described herein as a pFET. However, it is anticipated that the novel features of the MOSFET structure 100 of the invention can also be incorporated into an n-type field effect transistor (nFET).

A gate 102 is positioned the top surface 104 of a semiconductor layer 150 above the channel region 160. The gate 102 can, for example, comprise a gate dielectric layer adjacent to the top 104 of the semiconductor layer, a gate conductor layer (e.g., a polysilicon gate conductor) on the gate dielectric layer and a nitride cap layer on the gate conductor layer.

Sidewall spacers 105 are located adjacent to the opposing sidewalls 103a-b of the gate 102. The sidewall spacers 105 can be multi-layered and can, for example, comprise a first layer 115 (e.g., an oxide layer, such as a silicon dioxide layer) adjacent to the opposing sidewalls and a second layer 116 (e.g., a nitride layer, such as a silicon nitride layer) adjacent to the first layer 115.

The source/drain extension regions 106 are within the top surface 104 of the semiconductor layer 150 below the sidewall spacers 105 and doped with a first type dopant (e.g., a p-type dopant such as boron (B)). Particularly, the source/drain extension regions 106 can be positioned below the first and second layers 115 and 116 of the sidewall spacers 105 such that they extend slightly below the gate 102.

The halo regions 107 are below the source/drain extension regions 106. The halo regions 107 are highly doped with a second type dopant (e.g., an n-type dopant, such as phosphorus (P), arsenic (As) or antimony (Sb)). Depending upon the techniques used to form the halo regions 107, they may extend along the perimeter of the source/drain extension regions 106 up to the top surface 104 of the semiconductor layer 150.

The deep source/drain regions 109 can extend into the semiconductor layer 150 a predetermined depth 112 from the top surface 104 and are positioned laterally adjacent to the source/drain extension regions 106 and the halo regions 107 opposite the channel region 160. The deep source/drain regions 109 can comprise an epitaxially grown semiconductor material (e.g., an epitaxial silicon, an epitaxial silicon germanium, an epitaxial silicon carbide, an epitaxial silicon germanium carbide, etc.). The deep source/drain regions 109 can be bordered by shallow trench isolation regions 110.

The channel region 160 is positioned below the gate 102 (e.g., disposed within the gaps between the implanted source/drain extension regions 106 and between the implanted halo regions 107).

The transistor structure 100 further comprises buried isolation regions 108 (e.g., buried nitride or oxide regions) within the semiconductor layer 150 in order to suppress short channel effects. The buried isolation regions 108 can be positioned in the semiconductor layer 150 below the level of the source/drain extension regions 106 and between the deep source/drain regions 109 and the channel region 160 and, particularly, between the deep source/drain regions 109 and the halo regions 107. Buried isolation regions 108 between the deep source/drain regions 109 and channel region 160 minimize drain induced barrier lowering (DIBL) as well as punch through. Additionally, because the deep source/drain regions 109 and halo regions 107 are separated by the buried isolation regions 108, side-wall junction capacitance and junction leakage are also minimized.

The buried isolation regions 108 can be incorporated into both pFETs and nFETs. However, as mentioned above, pFETs are particularly susceptible to such short channel effects. Thus, also disclosed and illustrated in FIG. 1 are embodiments of complementary metal oxide semiconductor device (CMOS) structure 500 that comprises a pFET 100 coupled to an nFET 200 (e.g., an inverter).

In the CMOS structure 500, the active semiconductor regions of the nFET 200 and pFET 100 can be isolated from each other by shallow trench isolation structures 110. The pFET 100 can be configured, as described above. The nFET 200 can comprise a gate 202 above the semiconductor layer 150 and multi-layered sidewall spacers 205 can be adjacent opposing sidewalls 203a-b of the gate 202. The semiconductor layer 150 below the gate 202 of the nFET 200 can comprise a channel region 260, source/drain extension regions 206, and deep source/drain regions 209.

The nFET channel region 260 can be located below the gate 202 (e.g., disposed within the gap between the implanted source/drain extension regions 206 and between the implanted deep source/drain regions 209). The source/drain extensions regions 206 can be located in the semiconductor layer 150 immediately below the layers 215-216 of the sidewall spacers 205 such that they are extend slightly below gate 202. The deep source/drain regions 209 can extend laterally with the semiconductor layer 150 between the outer sidewall spacer layers 216 and the shallow trench isolation structures 110 and can extend vertically a predetermined distance into the semiconductor layer 150 such that they are deeper than the source/drain extension regions 206. The source/drain extension regions 206 and deep source/drain regions 209 can both be doped with an n-type dopant (e.g., phosphorus (P), arsenic (As) or antimony (Sb)).

As with the pFET 100, the nFET 200 can comprise halo regions 207 below the source/drain extension regions 206 and buried isolation regions (not shown) between the halo regions and the deep source/drain regions 209. However, because nFETs are not as susceptible to short channel effects as pFETs, the nFET 200 can also optionally be formed without the halo regions 207 and/or the buried isolation regions.

Also disclosed are embodiments of a method of forming a MOSFET structure and a method of forming a CMOS device that incorporates such a MOSFET structure. For the purpose of illustration and because p-type field effect transistors (pFETs) are more susceptible to short channel effects, the following discussion will describe embodiments of a method of forming a pFET having buried isolation regions that suppress short channel effects and a method of forming a CMOS device that incorporates such a pFET. However, it is anticipated that the novel features of the method embodiments described may also be used to form an n-type field effect transistor (nFET) having buried isolation regions that suppress short channel effects and a CMOS device that incorporates both an nFET and a pFET, one or both of which incorporate such buried isolation regions.

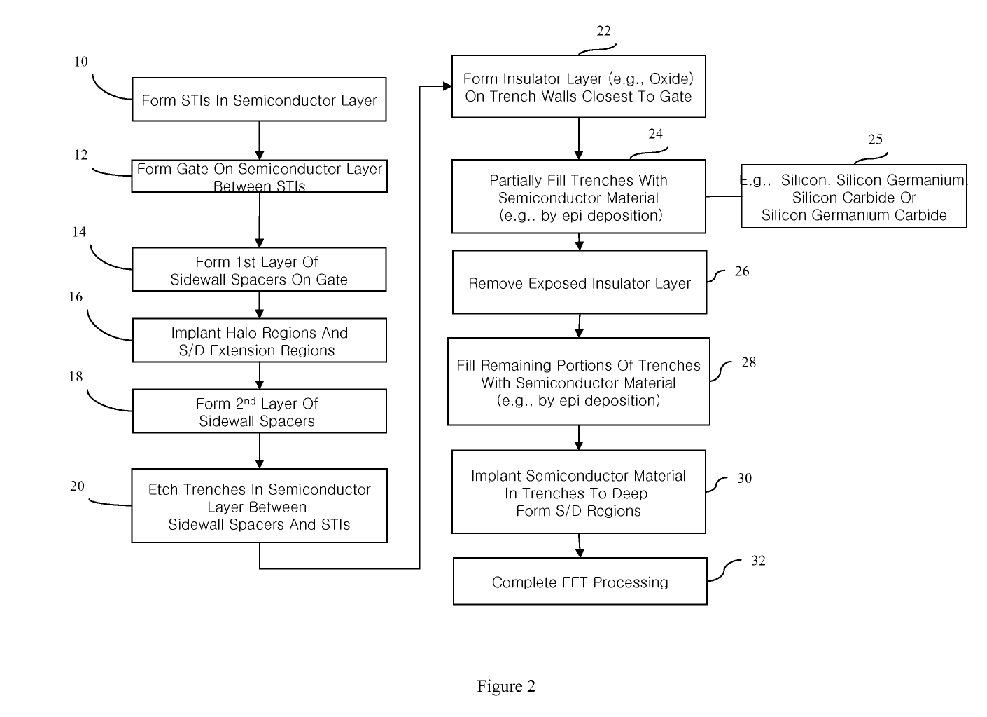

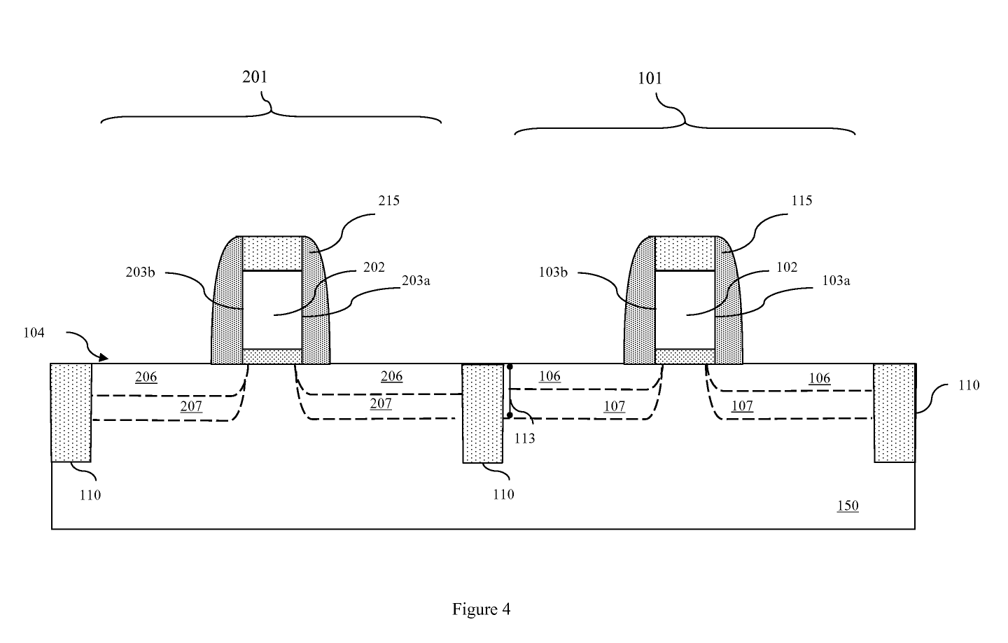

More particularly, referring to FIG. 2, an embodiment of a method of forming a MOSFET structure 100 comprises forming shallow trench isolation structures (STIs) 110 within a semiconductor layer 150 (e.g., a silicon layer of an silicon-on-insulator or bulk silicon wafer) in order to define an active semiconductor region (i.e., section 101) for the transistor (10, see FIG. 4).

A gate 102 is formed on a top surface 104 of the semiconductor layer 150 and, particularly, on the top surface of the semiconductor region 101 defined by the STIs 110 (12, see FIG. 4). The gate 102 can be formed by conventional processing techniques. For example, layers of a gate dielectric, a gate conductor and a nitride cap can be deposited and lithographically patterned to form the gate structure 102.

A first layer 115 (e.g., an oxide layer) of sidewall spacers is formed on the opposing sidewalls 103a-b of the gate 102 (e.g., using conventional sidewall spacer processing techniques in which spacer material is deposited and then directionally etched) (14, see FIG. 4). The width of the first layer 115 can be predetermined in order to limit the extent of lateral dopant diffusion from the subsequently formed source/drain extension regions 106 below the gate 102 (i.e., so that the source/drain extension regions 106 only slightly overlap the gate 102).

Then, a high concentration of a second type dopant (e.g., an n-type dopant such as phosphorus (P), arsenic (As) or antimony (Sb)) can be implanted a predetermined depth 113 into the semiconductor layer 150 on both sides 103a-b of the gate 102 in order to form halo regions 107. Additionally, a first type dopant (e.g., a p-type dopant such as boron (B)) can be implanted into the top surface 104 of the semiconductor layer 150 on both sides 103a-b of the gate 102 above the second type dopant (i.e., above the halo regions 107) in order to form source/drain extension regions 106 (16, see FIG. 4).

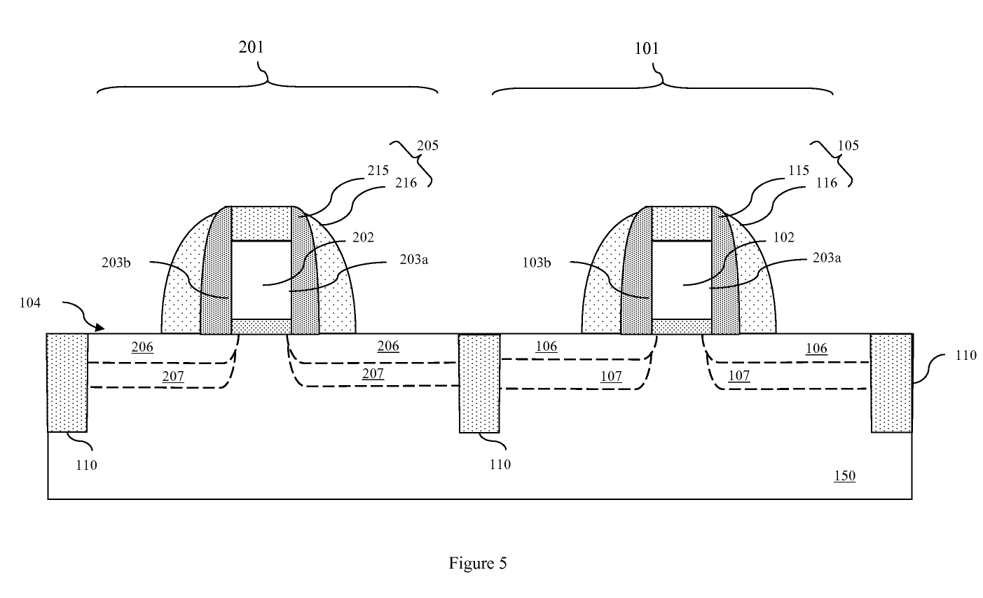

Once the source/drain extension regions 106 and the halo regions 107 are implanted, a second layer 116 (e.g., a nitride layer) of sidewall spacers is formed on the first layer 115. Thus, multi-layered sidewall spacers 105 are formed adjacent to the opposing sidewalls 103a-b of the gate 102 (18, see FIG. 5).

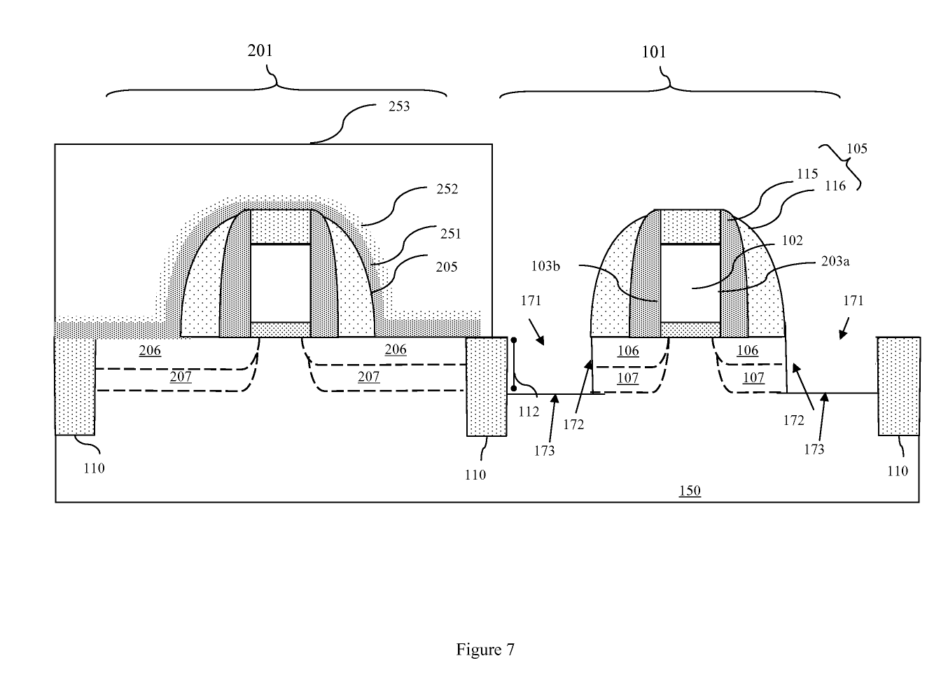

Trenches 171 are then etched into the semiconductor layer 150 on both sides of the gate 102 (20, see FIG. 7). The trenches 171 are etched (e.g., using a reactive ion etching process) such that they extend between the sidewall spacers 105 and the shallow trench isolation structures 110 that define the active silicon region 101. Thus, the trench walls 172 closest to the gate 102 are aligned below the sidewall spacers 105. Additionally, the bottom 173 of the trenches 171 and the trench walls 172 closest to the gate 102 comprise the semiconductor material of the semiconductor layer 150, whereas all of the other trench walls comprise the isolation material of the STIs 110. The depth 112 of the trenches 171 can be approximately equal to the predetermined depth 113 at which the second type dopant is implanted to form the halo regions 107.

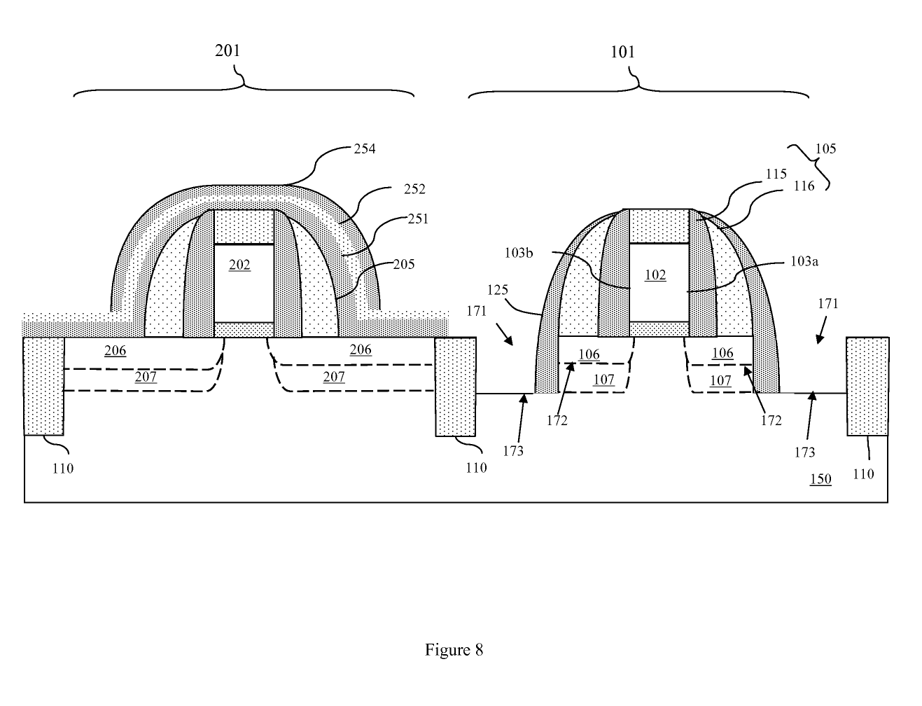

An insulator layer 125 (e.g., an oxide or nitride layer) is then formed on the trench walls 172 closest to the gate 102 (22, see FIG. 8). This can be accomplished, for example, by using conventional processing techniques to form additional sidewall spacers adjacent to the second layer 116 of the sidewall spacers 105. The additional sidewall spacers are formed such that they extend down to the bottoms 173 of the trenches 171 and cover the trench walls 172 closest to the gate 102. The additional sidewall spacers can be formed using an insulator material (e.g., an oxide or a nitride). Consequently, at this point in the formation process, the bottoms 173 of the trenches 171 comprise the semiconductor material that forms the semiconductor layer 150 and the sides comprise the insulating material from either the STIs 110 or the insulator layer 125.

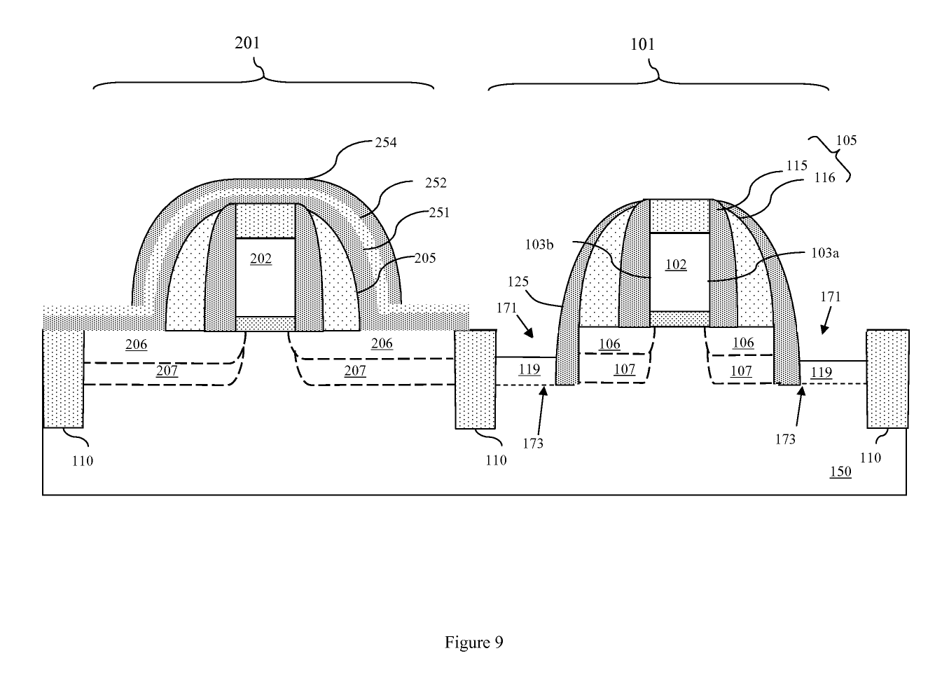

After the insulator layer 125 is formed, the trenches 171 can be partially filled with a selected semiconductor material 119 (24, see FIG. 9). For example, the trenches 171 can be filled such that the semiconductor material 119 is just below the level of the dopant implant for the source/drain extension regions 106. This can be accomplished by performing an epitaxial deposition process such that the selected semiconductor material 119 (e.g., silicon, silicon germanium, silicon carbide, silicon germanium carbide, etc.) is grown from the semiconductor layer 150 that is exposed at the bottom 173 of the trenches 171. The selected semiconductor material 119 is only grown vertically because the sides of the trenches are formed of insulating material from the STIs 110 or insulator layer 125.

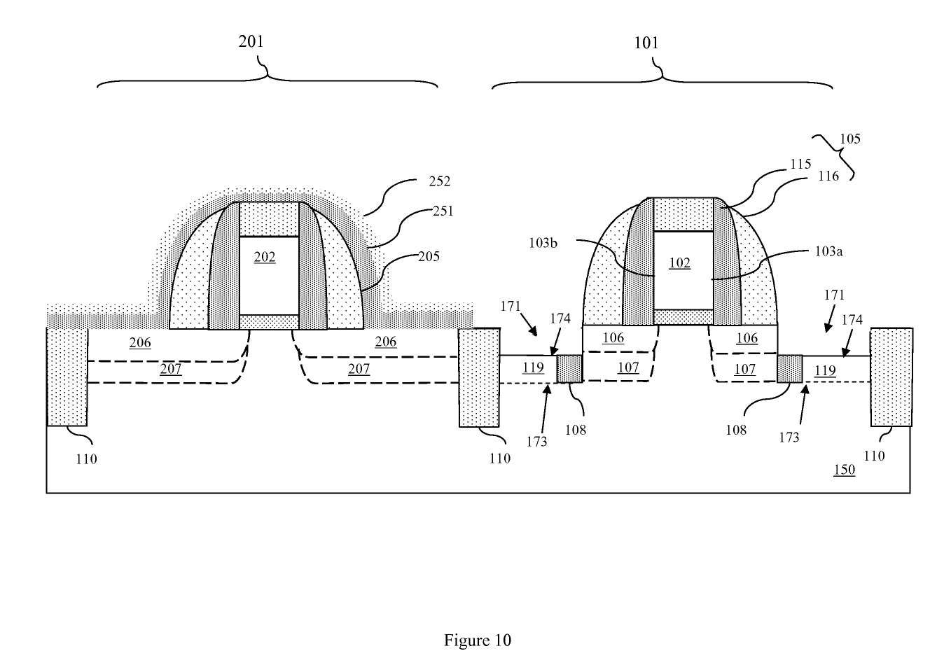

Once the trenches 171 are partially filled with the selected semiconductor material 119, the exposed portions of the insulator layer 125 (e.g., on the sidewall spacers 105 and within the trench 171 above the selected semiconductor material 119) are removed (e.g., by a selective etch process) such that only portion 108 of the insulator layer 125 remains (26, FIG. 10). Consequently, at this point in the formation process, the selected semiconductor material 119 is exposed at the bottom 174 of the partially filled trenches 171 and the semiconductor material of the semiconductor layer 150 is exposed at the trench walls 172 closest to the gate 102 above isolation regions 108.

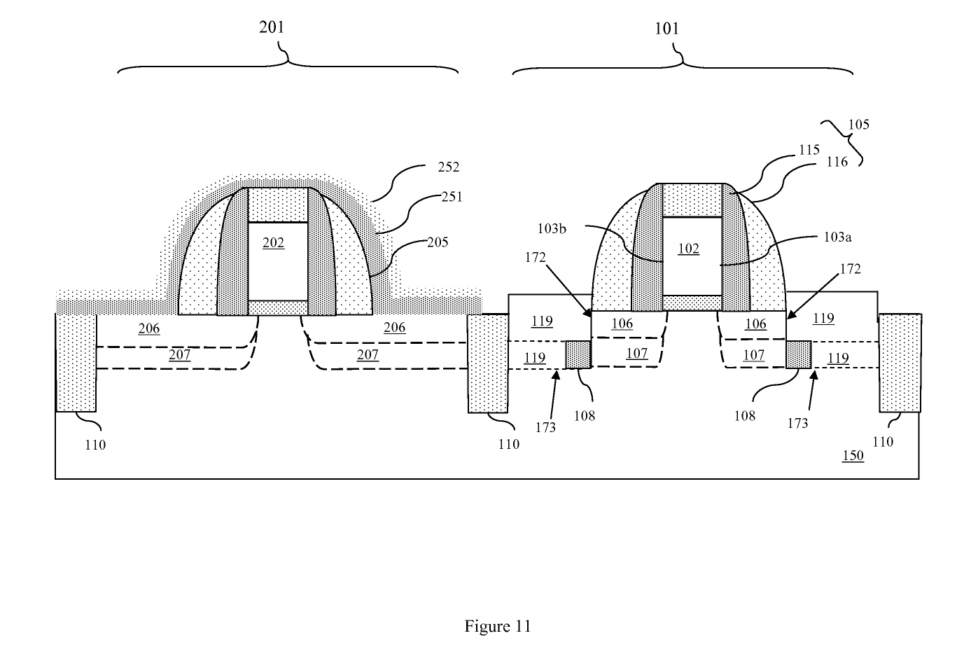

Then, a second epitaxial deposition process is performed in order to completely fill the trenches 171 with the selected semiconductor material 119 and, optionally, such that the selected semiconductor material 119 is raised above the top surface 104 of the semiconductor layer 150 on either side of the gate 102 (28, see FIG. 11). During this second epitaxial deposition process, the selected semiconductor material 119 is grown both vertically from the semiconductor material 119 that is already partially filling the trenches 171 and horizontally from the trench walls 172 exposed below the sidewall spacers 105 and above the remaining insulator layer 108.

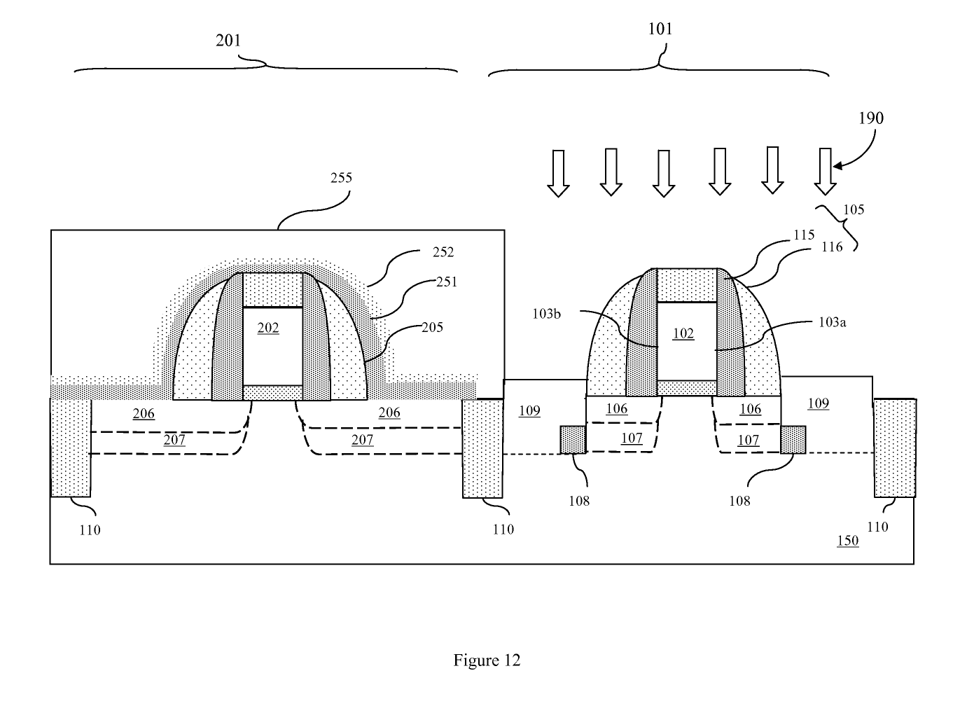

Once the trenches are completely filled with semiconductor material 119 and once the remaining insulator layer is buried (i.e., once the buried isolation regions 108 are formed), the selected semiconductor material within the trenches can be implanted with a first type dopant (e.g., a p-type dopant such as boron (B)) in order to form the deep source/drain regions 109 of pFET (30, see FIG. 12). These deep source/drain regions 109 are, thus, separated from the halo regions 107 as well as the channel region 160 below the gate 102 by the buried isolation regions 108.

Following implantation of the deep source/drain regions 109, conventional processing techniques can be used to complete the FET 100 (e.g., silicide formation, deposition of a blanket dielectric layer, contact formation, etc.) (32).

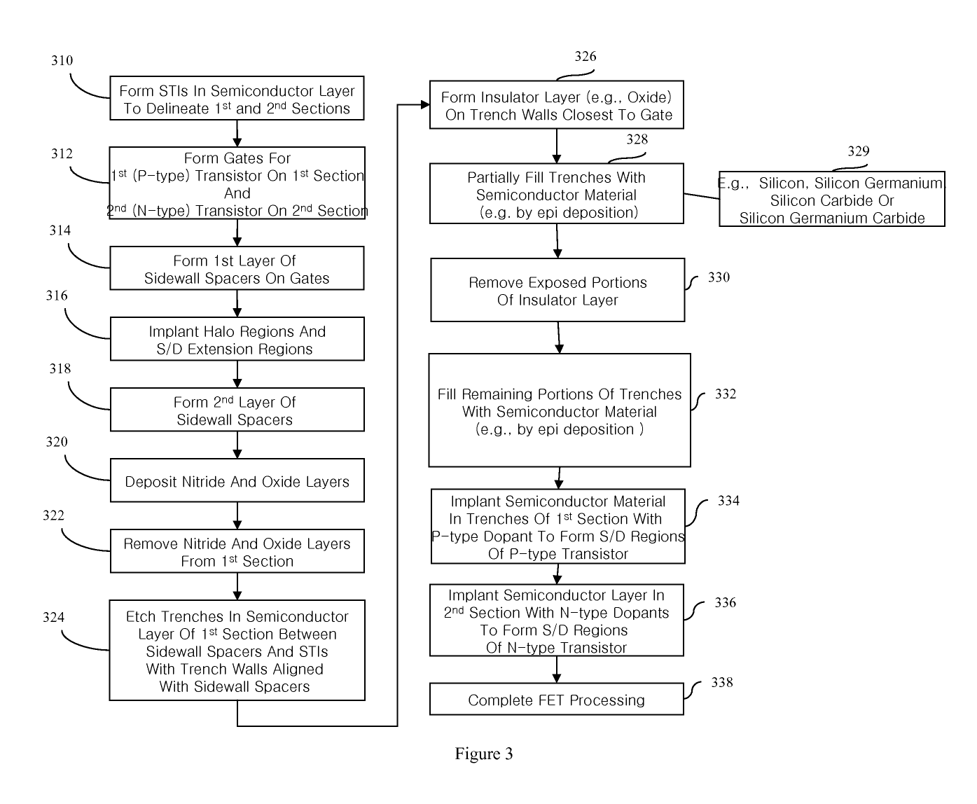

Referring to FIG. 3, an embodiment of a method of forming a CMOS device structure (e.g., an inverter) that incorporates such a MOSFET structure comprises forming shallow trench isolation structures (STIs) 110 within a semiconductor layer 150 to define the active semiconductor regions for multiple transistors. That is, the first section 101 of the semiconductor layer 150 can be delineated by STIs 110 for a first transistor (e.g., a p-type field effect transistor (pFET)) and a second section 201 of the semiconductor layer 150 can be delineated by STIs 110 for a second transistor (e.g., an n-type field effect transistor (nFET)) (310, see FIG. 4).

Then, a first gate 102 is formed on the first section 101 and a second gate 202 is formed on the second section 201 (312, see FIG. 4). The gates 102, 202 can be formed by conventional processing techniques. For example, layers of a gate dielectric, a gate conductor and a nitride cap can be deposited and lithographically patterned to form the gate structures 102, 202.

A first layer 115, 215 (e.g., an oxide layer) of sidewall spacers is formed on the opposing sidewalls 103a-b, 203a-b of the first and second gates 102, 202 (e.g., using conventional sidewall spacer processing techniques in which a blanket layer of spacer material is deposited and then directionally etched) (314, see FIG. 4). The width of the first layer 115, 215 can be predetermined in order to limit the extent of lateral dopant diffusion from the subsequently implanted source/drain extension regions 106, 206 below the gates 102, 202 (i.e., so that the source/drain extension regions 106, 206 only slightly overlap the gates 102, 202, respectively).

Then, masked implantation processes can be used to form halo regions 107 for the pFET in the first section 101 and, optionally, halo regions for the nFET in the second section 201 (316, see FIG. 4). Masked implantation processes can also be used to form source/drain extension regions 106, 206 for both the pFET and nFET. Specifically, a second type dopant (e.g., an n-type dopant such as phosphorus (P), arsenic (As) or antimony (Sb)) can be implanted a predetermined depth into the semiconductor layer 150 on both sides of the first gate 102 in order to form halo regions 107 for the pFET and a first type dopant (e.g., a p-type dopant such as boron (B)) can be implanted a predetermined depth into the semiconductor layer 150 on both sides of the second gate 202 in order to form halo regions 207 for the nFET. Additionally, a first type dopant (e.g., a p-type dopant) can be implanted into the top surface 104 of the semiconductor layer 150 on both sides of the first gate 102 above the second type dopant (i.e., above the halo regions 107) in order to form source/drain extension regions 106 for the pFET and a second type dopant (e.g., an n-type dopant) can be implanted into the top surface 104 of the semiconductor layer 150 on both sides of the second gate 202 (i.e., above the halo regions 207) in order to form source/drain extension regions 206 for the nFET.

Once the source/drain extension regions and the halo regions are implanted at process 316, a second layer 116, 216 of sidewall spacers (e.g., a nitride layer) is formed on the first layer 115, 215 of sidewall spacers 115, 215 each gate 102, 202 (318, see FIG. 5). As with the first layer 115, 215, the second layer 116, 216 of sidewall spacers can be formed using conventional sidewall spacer processing techniques in which spacer material is deposited and then directionally etched. Thus, multi-layered sidewall spacers 105, 205 are formed adjacent to the opposing sidewalls 103a-b, 203a-b of both the first and second gates 102, 202.

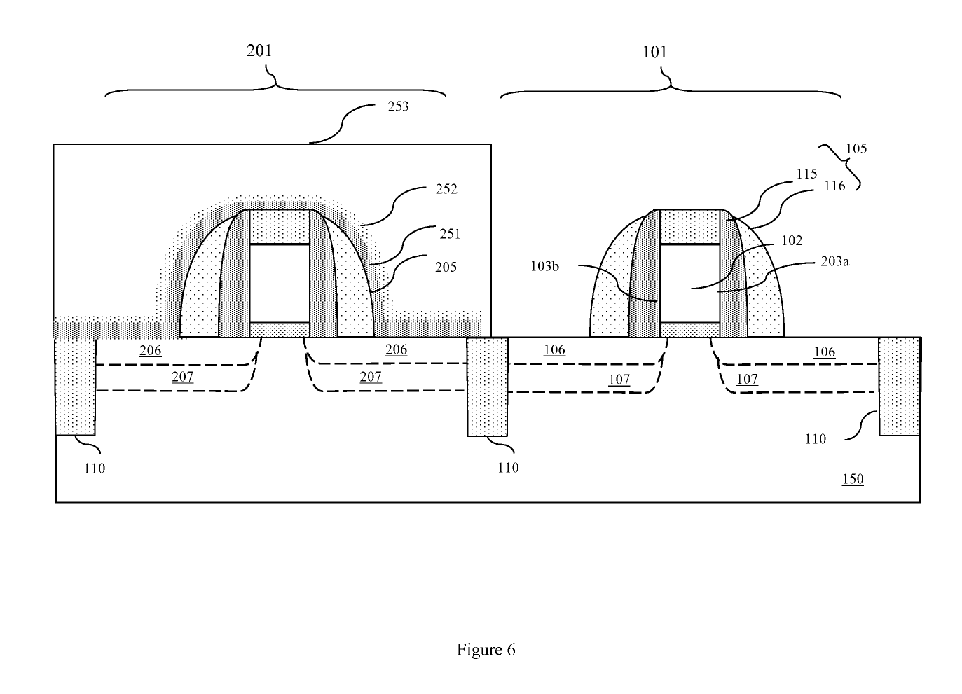

After formation of the second sidewall spacer layer 116, 216, blanket layers of silicon dioxide (SiO₂) 251 and silicon nitride 252 can be deposited over the first and second section 101, 201 (320). Then a mask 253 is lithographically patterned above the second section 201 and the oxide and nitride layers 251, 252 are selectively removed from above the first section 101 (322, see FIG. 6).

Then, trenches 171 are etched into the semiconductor layer 150 in the first section 101 on both sides of the first gate 102 (324). The trenches 171 are etched (e.g., using a reactive ion etching process) such that they extend between the sidewall spacers 105 and the shallow trench isolation structures 110 that define section 101. Thus, the trench walls 172 closest to the gate 102 are aligned below the sidewall spacers 105. Additionally, the bottom 173 of the trenches 171 and the trench walls 172 closest to the gate 102 comprise the semiconductor material of the semiconductor layer 150, whereas all of the other trench walls comprise the isolation material of the STIs 110. The depth 112 of the trenches 171 can be approximately equal to the predetermined depth 113 at which the dopant is implanted to form the halo regions 107.

An insulator layer 125 is then formed on the trench walls 173 closest to the first gate 102. This can be accomplished, for example, by using conventional processing techniques to form additional sidewall spacers adjacent to the second layer 116 of the sidewall spacers 105. The additional sidewall spacers are formed such that they extend down to the bottoms 173 of the trenches 171 and cover the trench walls 172 closest to the gate 102. The additional sidewall spacers can be formed using an insulator material (e.g., an oxide or a nitride). Prior to the formation of the additional sidewall spacers, the mask 253 over the second section 201 may be removed and the additional sidewall spacers can also simultaneously be formed on the second gate structure 202.

Consequently, at this point in the formation process, the bottoms 173 of the trenches 171 comprise the semiconductor material that forms the semiconductor layer 150 and the sides comprise the insulating material from either the STIs 110 or the insulator layer 125.

After the insulator layer 125 is formed, the trenches 171 can be partially filled with a selected semiconductor material 119 (328, see FIG. 9). For example, the trenches 171 can be filled such that the semiconductor material 119 is just below the level of the dopant implant for the source/drain extension regions 106. This can be accomplished by performing an epitaxial deposition process such that the selected semiconductor material 119 (e.g., silicon, silicon germanium, silicon carbide, silicon germanium carbide, etc.) is grown from the semiconductor layer 150 that is exposed at the bottom 173 of the trenches 171. The selected semiconductor material 119 is only grown vertically because the sides of the trenches are formed of insulating material from the STIs 110 or insulator layer 125. The nitride and oxide layers 251, 252 protect the second section 201 during this epitaxial deposition process.

Once the trenches 171 are partially filled with the selected semiconductor material 119, the exposed portions of the insulator layer 125 (e.g., on the sidewall spacers 105 and within the trench 171 above the selected semiconductor material 119) are removed (e.g., by a selective etch process) such that only portion 108 of the insulator layer 125 remains (330, FIG. 10). Consequently, at this point in the formation process, the selected semiconductor material 119 is exposed at the bottom 174 of the partially filled trenches 171 and the semiconductor material of the semiconductor layer 150 is exposed at the trench walls 172 closest to the gate 102 above isolation regions 108.

Then, a second epitaxial deposition process is performed in order to completely fill the trenches 171 with the selected semiconductor material 119 and, optionally, such that the selected semiconductor material 119 is raised above the top surface 104 of the semiconductor layer 150 on either side of the gate 102 (332, see FIG. 11). During this second epitaxial deposition process, the selected semiconductor material 119 is grown both vertically from the semiconductor material 119 that is already partially filling the trenches 171 and horizontally from the trench walls 172 exposed below the sidewall spacers 105 and above the remaining insulator layer 108. Again, the nitride and oxide layers 251, 252 protect the second section 201 during this epitaxial deposition process.

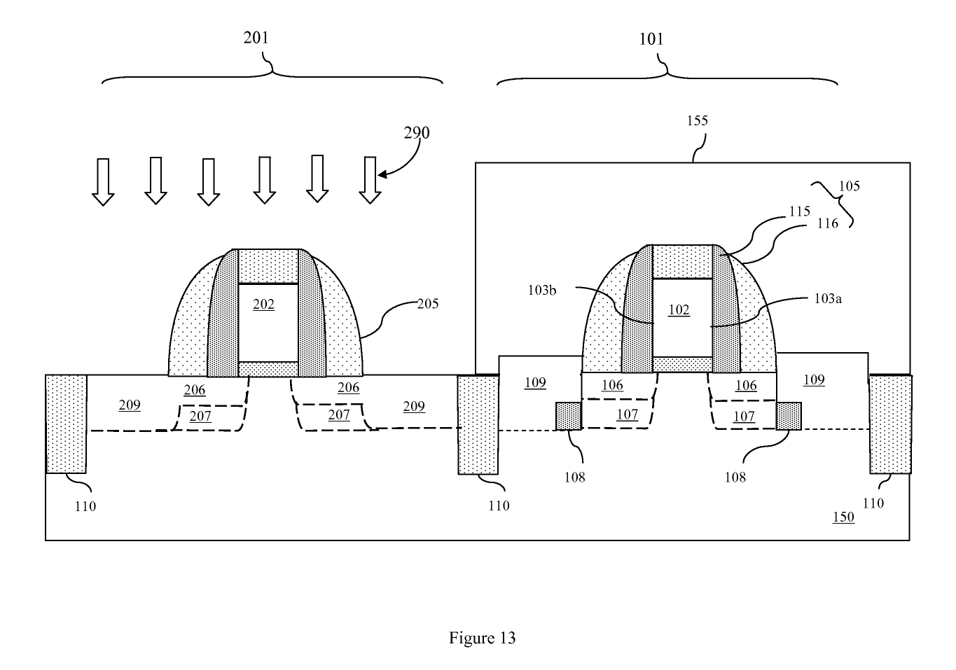

Once the trenches are completely filled with semiconductor material 119 and once the remaining insulator layer is buried (i.e., once the buried isolation regions 108 are formed), masked implantation processes can be used to form the deep source/drain regions 109, 209 in both the first and second section (334-336). That is, a mask 255 can be lithographically patterned above the second section 201 and the selected semiconductor material 119 within the trenches 171 can be implanted with a first type dopant 190 (e.g., a p-type dopant such as boron (B)) in order to form the deep source/drain regions 109 for a pFET (334, see FIG. 12). These deep source/drain regions 109 are, thus, separated from the halo regions 107 as well as the channel region 160 of the pFET in section 101 by the buried isolation regions 108. After formation of the source/drain regions 109 in the first section 101, the mask 255 can be removed and another mask 155 can be lithographically patterned over the first section 101. Then, the nitride and oxide layers 251-252 can be removed from the second section 201 and the semiconductor layer 150 on both sides of the spacers 205 can be implanted with a second-type dopant 290 (e.g., an n-type dopant such as phosphorus (P), arsenic (As) or antimony (Sb)) to form the deep source/drain regions 209 of the nFET (336, FIG. 13).

Following implantation of the deep source/drain regions 109, 209, conventional processing techniques can be used to complete the FET 100 (e.g., silicide formation, deposition of a blanket dielectric layer, contact formation, etc.) (338).

Therefore, disclosed are embodiments of improved MOSFET and CMOS structures that provides for increased control over short channel effects. Also disclosed are embodiments of associated methods of forming these structures. The embodiments suppress short channel effects by incorporating buried isolation regions into a transistor below source/drain extension regions and between deep source/drain regions and the channel region and, particularly, between deep source/drain regions and the halo regions. Buried isolation regions between the deep source/drain regions and the channel region minimize drain induced barrier lowering (DIBL) as well as punch through. Additionally, because the deep source/drain regions and halo regions are separated by the buried isolation regions, side-wall junction capacitance and junction leakage are also minimized.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, those skilled in the art will recognize that the embodiments of the invention can be practiced with modification within the spirit and scope of the appended claims.

What is claimed is:

1. A method of forming a transistor comprising:
forming a gate on a semiconductor layer;
forming sidewall spacers adjacent to opposing sidewalls of said gate;
etching trenches into said semiconductor layer such that trench walls are aligned with said sidewall spacers;
forming an insulator layer adjacent to said trench sidewalls;
partially filling said trenches with a semiconductor material;
removing exposed portions of said insulator layer; and
after said removing of said exposed portions, completely filling said trenches with said semiconductor material.

2. The method of claim 1, further comprising implanting said semiconductor material in said trenches with a first type dopant.

3. The method of claim 1,
wherein said forming of said sidewall spacers comprises forming a first layer of said sidewall spacers on said opposing sidewalls of said gate and forming a second layer of said sidewall spacers on said first layer, and
wherein said method further comprises, before said forming of said second layer, implanting a second type dopant a predetermined depth into said semiconductor layer on both sides of said gate.

4. The method of claim 3, wherein said trenches are etched to a depth that is approximately equal to said predetermined depth.

5. The method of claim 3, further comprising, after said implanting of said second type dopant and before said forming of said second layer, implanting a first type dopant into said top surface of said semiconductor layer on both sides of said gate above said second type dopant.

6. The method of claim 1, wherein said insulator layer comprises one of a nitride and an oxide.

7. The method of claim 1, further comprising,
before said forming of said gate, forming shallow trench isolation structures within said semiconductor layer,
wherein said etching of said trenches further comprises etching said trenches such that said trenches extend between said sidewall spacers and said shallow trench isolation structures, and
wherein said partially filling of said trenches comprises performing an epitaxial deposition process such that said semiconductor material is only grown vertically from said semiconductor layer that is exposed at the bottom of said trenches.

8. The method of claim 7, wherein said filling of said remaining portions of said trenches comprises performing a second epitaxial deposition process such that said semiconductor material is grown both vertically from said semiconductor material partially filling said trenches and horizontally from said trench walls exposed below said sidewall spacers.

9. The method of claim 1, wherein said semiconductor material comprises one of silicon, silicon germanium, silicon carbide, and silicon germanium carbide.

10. A method of forming a complementary metal oxide semiconductor device comprising:
forming a first gate on a first section of a semiconductor layer and a second gate for on a second section of said semiconductor layer;
forming sidewall spacers adjacent to opposing sidewalls of said first gate and said second gate;
etching trenches into said semiconductor layer in said first section such that trench walls are aligned with said sidewall spacers on said first gate;
forming an insulator layer adjacent to said trench walls;
partially filling said trenches with a semiconductor material;
removing exposed portions of said insulator layer; and
after said removing of said exposed portions, completely filling said trenches with said semiconductor material.

11. The method of claim 10,
wherein said forming of said sidewall spacers comprises forming a first layer of said sidewall spacers on said opposing sidewalls of said first gate and said second gate and forming a second layer of said sidewall spacers on said first layer, and
wherein said method further comprises, before said forming of said second layer,
implanting an n-type dopant a predetermined depth into said semiconductor layer on both sides of said first gate;
implanting a p-type dopant at said top surface of said semiconductor layer on both sides of said first gate above said n-type dopant; and
implanting said n-type dopant at said top surface of said semiconductor layer on both sides of said second gate.

12. The method of claim 10, further comprising implanting said semiconductor material in said trenches with a p-type dopant.

13. The method of claim 10, further comprising,
before said forming of said first gate and said second gate, forming shallow trench isolation structures within said semiconductor layer,
wherein said etching of said trenches further comprises etching said trenches such that said trenches extend between said sidewall spacers on said first gate and said shallow trench isolation structures, and
wherein said partially filling of said trenches comprises performing an epitaxial deposition process such that one of silicon, silicon germanium, silicon carbide, and silicon germanium carbide is only grown vertically from said semiconductor layer that is exposed at the bottom of said trenches.

14. The method of claim 13, wherein said filling of said remaining portions of said trenches comprises performing a second epitaxial deposition process such that said one of silicon, silicon germanium, silicon carbide, and silicon germanium carbide is grown both vertically from said semiconductor material partially filling said trenches and horizontally from said trench walls exposed below said sidewall spacers on said first gate.

15. A semiconductor device comprising:
a transistor comprising:
a semiconductor layer;
a gate with opposing sidewalls on a top surface of said semiconductor layer;
sidewall spacers adjacent to said opposing sidewalls, wherein said semiconductor layer further comprises:
source/drain extension regions at said top surface below said sidewall spacers;
halo regions below said source/drain extension regions; and
source/drain regions adjacent to said source/drain extension regions and said halo regions; and
isolation regions within said semiconductor layer between said source/drain regions and said halo regions.

16. The device of claim 15, wherein said isolation regions comprise one of a nitride and an oxide.

17. The device of claim 15, wherein said source/drain regions comprise one of epitaxial silicon, epitaxial silicon germanium, epitaxial silicon carbide, and epitaxial silicon germanium carbide.

18. The device of claim 15, wherein said transistor is a p-type transistor and wherein said source/drain regions are doped with a p-type dopant.

19. The device of claim 18, wherein said halo regions are doped with an n-type dopant.

20. The device of claim 18, further comprising a second transistor coupled to said first transistor, wherein said second transistor is an n-type transistor.
